(19) United States
(12) Patent Application Publication
(10) Pub. No.: US 2025/0183619 A1
(43) Pub. Date: Jun. 5, 2025

(54) INTEGRATED POCKELS LASER DEVICE

(71) Applicant: University of Rochester, Rochester, NY (US)

(72) Inventors: Qiang Lin, Pittsford, NY (US); Mingxiao Li, Isla Vista, CA (US)

(73) Assignee: University of Rochester, Rochester, NY (US)

(21) Appl. No.: 18/840,346

(22) PCT Filed: Feb. 23, 2023
(86) PCT No.: PCT/US2023/013686

§ 371 Date: Aug. 21, 2024

Related U.S. Application Data
(60) Provisional application No. 63/268,511, filed on Feb. 25, 2022.

(51) Int. Cl. H01S 5/14; H01S 5/06

(52) U.S. Cl. CPC H01S 5/145; H01S 5/0614

(57) ABSTRACT

A lithium niobate (LN) external cavity includes a Vernier mirror structure which includes two or more microresonators where: one or more or all of the Vernier microresonators are tuned by the electro-optic Pockels effect of LN, with tuning electrodes integrated with the resonators, and one of the Vernier microresonators could be tuned by the thermo-optic effect, with a local heater integrated with the resonator. One or more or all of the Vernier microresonators include a section or the whole resonator that is periodically poled to achieve quasi-phase matching for nonlinear frequency conversion directly inside the laser cavity. The lithium niobate (LN) external cavity also includes a phase shifter whose phase is tuned by the electro-optic Pockels effect of LN. A Sagnac loop mirror is placed at the end of the device to function as the output end mirror of the laser cavity.

### CROSS-REFERENCE TO RELATED APPLICATIONS

This application claims priority to and the benefit of U.S. provisional patent application Ser. No. 63/268,511 INTEGRATED POCKELS LASER DEVICE, filed Feb. 25, 2022, the contents of which are incorporated herein by reference in its entirety.

### STATEMENT REGARDING FEDERALLY FUNDED RESEARCH OR DEVELOPMENT

This invention was made with government support under Defense Advanced Research Projects Agency (DARPA) LUMOS program under Agreement No. HR001-20-2-0044, the Defense Threat Reduction Agency-Joint Science and Technology Office for Chemical and Biological Defense (grant No. HDTRA11810047), and the National Science Foundation (NSF) (ECCS-1810169, ECCS-1842691 and, OMA-2138174). The government has certain rights in the invention.

### FIELD OF THE APPLICATION

The application relates to laser devices, particularly to integrated laser devices.

### BACKGROUND

Integrated semiconductor lasers are at the core of all integrated photonics. After half of a century of development, there have been primarily two categories of integrated semiconductor lasers: pure III-V lasers on native substrate and the integrated external cavity diode laser where III-V sections are coupled to external cavities usually made of Si/SiN. Although these lasers have shown great performance in many aspects that led to remarkable success in applications such as communication and sensing, some essential functions are still missing in the current integrated laser family. In particular, two major challenges, the lack of fast reconfigurability and the narrow spectral window limited by the epitaxial growth, have become the major bottleneck that stalls the progression of many evolving applications.

### SUMMARY

A lithium niobate (LN) external cavity includes a Vernier mirror structure which includes two or more microresonators where: one or more or all of the Vernier microresonators are tuned by the electro-optic Pockels effect of LN, with tuning electrodes integrated with the resonators, and one of the Vernier microresonators may be tuned by the thermo-optic effect, with a local heater integrated with the resonator. One or more or all of the Vernier microresonators include a section or the whole resonator that is periodically poled to achieve quasi-phase matching for nonlinear frequency conversion directly inside the laser cavity. The lithium niobate (LN) external cavity also includes a phase shifter whose phase is tuned by the electro-optic Pockels effect of LN. A Sagnac loop mirror is placed at the end of the device to function as the output end mirror of the laser cavity.

In illustrative embodiments, a laser apparatus, comprises a lithium-niobate-on-insulator (LNOI) substrate having a III/V gain element, a Vernier mirror structure on the (LNOI) substrate, including two or more microresonators each having one or more tuning electrodes. At least one of the microresonators is tuned by an electro-optic Pockels effect of lithium niobate (LN) in the cavity structure of the LNOI substrate.

The foregoing and other aspects, features, and advantages of the application will become more apparent from the following description and from the claims.

### BRIEF DESCRIPTION OF THE DRAWINGS

The features of the application can be better understood with reference to the drawings described below, and the claims. The drawings are not necessarily to scale, emphasis instead generally being placed upon illustrating the principles described herein. In the drawings, like numerals are used to indicate like parts throughout the various views.

FIG. 1 is a schematic view of one exemplative embodiment of the laser apparatus in accordance with the principles of the present disclosure;

FIG. 2 is a schematic view of another exemplative embodiment of the laser apparatus in accordance with the principles of the present disclosure;

FIG. 3 is a schematic view of another exemplative embodiment of the laser apparatus in accordance with the principles of the present disclosure;

FIG. 4 is a schematic view of another exemplative embodiment of the laser apparatus in accordance with the principles of the present disclosure;

### DETAILED DESCRIPTION

The field of integrated semiconductor lasers has made many advances over the last few decades, spanning information technologies to fundamental science. Using wafer-scale fabrication processes, these devices dramatically reduce the form factor of traditional bench-top laser equipment, and offer much lower power consumption and cost. Early laser designs were based entirely upon III-V semiconductors, configured either as Fabry-Perot cavities emitting multiple wavelengths, or as distributed-feedback (DFB) designs for single frequency emission. Besides providing coherent light generation across many applications, these devices serve as the key building block in on-chip systems by driving photonic integrated circuits (PICs).

With the continuing success of silicon photonics, integrated lasers have adopted passive cavities that are coupled to a III-V gain section. Endowed with enhanced photon lifetimes as well as reconfigurability, these integrated external-cavity-diode-laser (ECDL) structures, by mimicking their bulk counterparts, have significantly improved coherence and tunability in integrated photonics. Even more recently, with remarkable progress in fabrication of low loss Si/SiN waveguides, the linewidths of integrated lasers are now comparable to those of state-of-the-art bench top ECDLs and even fiber lasers. Such advances in coherence dramatically improves data capacity in communications as well as accuracy in on-chip sensing and frequency metrology systems.

However, despite these impressive achievements, key functions are missing in current integrated lasers. One outstanding problem lies in fast tuning and reconfigurability. Applications such as LiDAR require frequency modulation and tuning with high linearity and speed beyond the MHz level. In bench-top laser systems, these are usually realized by fast mechanical motion of components in an external cavity, but similar strategies in integrated photonics are far more challenging. Most often, frequency tuning of integrated lasers relies on the thermo-optic (TO) effect, which is relatively slow (kHz-level speed). And even while MHZ-level frequency tuning can be achieved by current sweep of the III-V gain medium, this carrier-induced effect produces unwanted intensity modulation. This same limitation of integrated lasers is compounded by their limited spectrum in application to atomic physics, where switching speeds up to MHz level are required for ion/atom manipulation, but at visible and near visible bands. Here, in contrast to free-space laser cavities where nonlinear media can be readily implemented within the resonator to generate short-wavelength light by frequency conversion, an integrated nonlinear cavity suitable for electrical pumping has so far remained elusive. In these visible/near-visible applications, integrated photonics must rely on very challenging design, growth, and processing developments using new gain media. The resulting difficulties have presented a bottleneck to on-chip solutions in a wide range of evolving applications.

The development of integrated semiconductor lasers has miniaturized traditional bulky laser systems, enabling a wide range of photonic applications. A progression from pure III-V based lasers to III-V/external cavity structures has harnessed low-loss waveguides in different material systems, leading to significant improvements in laser coherence and stability. Despite these successes, however, key functions remain absent. In illustrative embodiments, a critical missing function is realized in miniaturized laser systems by integrating the Pockels effect into a semiconductor laser. Using a hybrid integrated III-V/Lithium Niobate structure, several essential capabilities are demonstrated that have not existed in previous integrated lasers. These include frequency modulation at 2 hexahertz(s) (2.0×10¹⁸ Hz/s) and switching at 50 MHz, both of which are record levels made possible by integration of the electro-optic effect. Moreover, the device co-lases at infrared and visible frequencies via the second-harmonic frequency conversion process, the first such integrated multi-color laser. Combined with its narrow linewidth and wide tunability, this new type of integrated laser holds promise for many applications including LiDAR, microwave photonics, atomic physics, and AR/VR.

Moreover, a new type of integrated semiconductor laser, the Pockels laser, according to the principles of the present disclosure is disclosed. In illustrative embodiments, the laser is formed by a Vernier-resonator-based external cavity on a lithium-niobate-on-insulator (LNOI) platform integrated with a III-V gain element. The laser uses the strong electro-optic Pockels effect of lithium niobate (LN) for ultrafast tuning and reconfiguration of the laser, with a speed unprecedented by any integrated lasers demonstrated to date. The laser also utilizes the strong quadratic optical nonlinearity of LN for frequency conversion directly inside the laser cavity, which emits light anywhere from ultraviolet to mid infrared, with laser wavelengths by design, supporting unique multi-color lasing.

Otherwise stated, in illustrative embodiments, a new family of lasers, the Pockels laser, is disclosed to fill long-standing deficiencies in the integrated photonics paradigm. By using lithium-niobate-on-insulator (LNOI) waveguide elements to form an external cavity, a III-V gain section with the Pockels effect in an integrated laser is developed. This adds several new capabilities to on-chip lasers including fast on-chip reconfigurability with laser-frequency tuning at a record speed of 2.0 EHz/s, as well as switching at a record high rate of 50 MHz. On account of the low required drive voltages, these functions can be directly driven by CMOS signals. Furthermore, using an intracavity periodically poled lithium niobate (PPLN) waveguide section embedded in one of the Vernier rings, first multi-color integrated laser is disclosed and described herein. The illustrative laser emits high-coherence light at telecommunication wavelengths and in the visible band via frequency conversion through second harmonic generation (SHG).

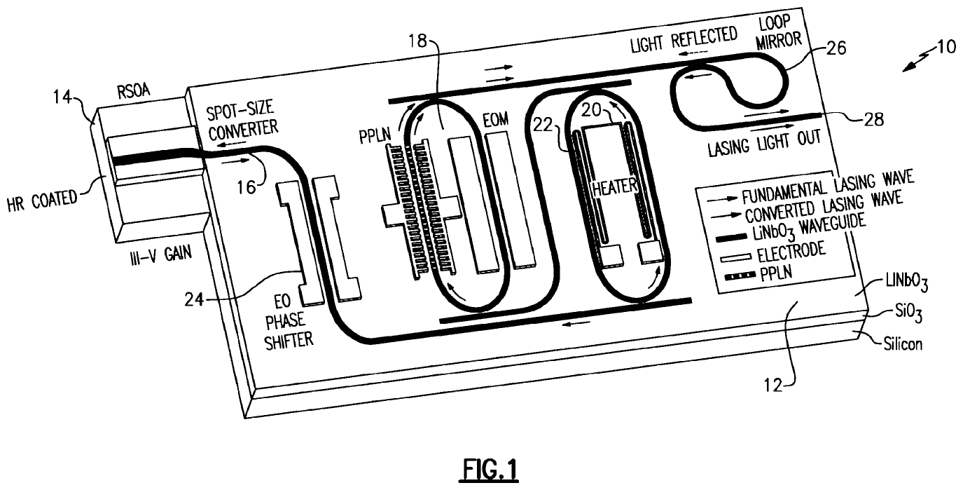

FIG. 1 is a schematic view of one illustrative embodiment of the laser apparatus 10 of the present disclosure. In general, the lithium niobate (LN) external cavity includes of the following elements:
A Vernier mirror structure having two or more microresonators where:
One or more or all of the Vernier microresonators are tuned by the electro-optic Pockels effect of LN, with tuning electrodes integrated with the resonators. One of the Vernier microresonators could be tuned by the thermo-optic effect, with a local heater integrated with the resonator.
One or more or all of the Vernier microresonators include a section or the whole resonator that is periodically poled to achieve quasi-phase matching for nonlinear frequency conversion directly inside the laser cavity.
A phase shifter whose phase is tuned by the electro-optic Pockels effect of LN.
a Sagnac loop mirror is placed at the end of the device to function as the output end mirror of the laser cavity.

More specifically, the laser apparatus 10 includes a lithium-niobate-on-insulator (LNOI) substrate or chip 12 which forms at least part of the external cavity structure or chip of the apparatus. Lithium niobate (LN) is a crystal material that is typically used to create wafers for use in photonic, piezoelectric, and electro-optic applications. These wafers are typically thin and flat, and are produced through processes such as crystal growth, slicing, and polishing. Lithium niobate (LN) is well-known for its superior capability in optical modulation and frequency conversion. The laser structure shown in FIG. 1, includes a III-V reflective semiconductor optical amplifier (RSOA) 14 edge-coupled to an external cavity on the LNOI chip 12. Lithium niobate (LN) is well-known for its superior capability in optical modulation and frequency conversion. A laser cavity built upon would enable intriguing laser functionalities significantly beyond the reach of conventional integrated lasers, as we will show in detail below. To avoid mode mismatch between the RSOA 14 and LNOI chip 12, a spot-size converter 16 is adopted in the system, obtaining a minimal mode mismatch between a III-V waveguide and a 5-μm-wide 600-nm-thick LNOI waveguide, whose mode profiles are shown in the Supplementary Materials (SM). To minimize facet reflection, the III-V facet is coated with anti-reflective (AR) layers, and LNOI's input-facet coupling waveguide is angled by 10 degrees to achieve a reduced reflectivity (around 10% simulated by FDTD Lumerical) to match the angle of injected light. The reflectivity can be further reduced by applying AR coating to LNOI's input-facet.

The LNOI external cavity is a Vernier mirror structure consisting of two racetrack resonators 18, 20. The geometry of the racetrack resonators and bus waveguides are tailored to minimize the number of coupled mode families to avoid multi-mode lasing. The coupling is carefully selected by taking the lasing power, laser linewidth, and the tuning speed of the cavity into consideration. The free spectral range (FSR) of the microresonators is set to be 70 GHz, with a 2 GHz difference between the two resonators, which corresponds to a Vernier FSR of 2.4 THz. The shape of the racetrack(s) is optimized with the trade-off between the EO modulation efficiency that requires a long straight section, and the optical scattering loss that requires a large curvature radius. As a result, an Euler curve profile is employed to minimize the scattering loss while maximizing the length of the racetrack. The polarization of the fundamental quasi-transverse-electric (quasi-TE) mode is aligned to harness the large Pockels effect of LN (r33=30 pm/V, d33=19.5 pm/V [34]) at the straight section of the racetrack.

To combine versatile functions into one laser structure, each of the microresonators 18, 20 is designed for a different purpose. The first microresonator 18 is integrated with driving electrodes designed for high-speed EO tuning. The second microresonator 20 includes a micro heater 22 for broad wavelength tuning. Furthermore, a tunable phase control shifter 24 is also implemented in the cavity to align the longitudinal laser cavity mode with the Vernier mode. Benefiting from the strong EO Pockels effect in LN, the phase-control shifter 24 is operated via the EO effect instead of the commonly used TO effect. In contrast to the conventional TO approach that is slow (kHz-speed), power hungry and suffers from the thermal crosstalk problem, the EO Pockels approach enables high-speed, energy efficient, and independent control of individual functionalities as we will show below. Finally, a Sagnac loop ring 26 is placed at the end of the device to function as the output end mirror 28 of the laser cavity. The output-facet waveguide is designed for optimized coupling to a tapered fiber for performance characterization.

In operation, laser light from the RSOA 14 is coupled relative to the LNOI chip 12 through the spot-size converter 14. The EO phase control shifter 24 receives the output of the converter 14. Light passing through the phase control shifter 24 is input into the first microresonator 18, whereby the output of the first microresonator 18 is input into the second microresonator 20. The output from the output end of the second microresonator 20 enters the Sagnac loop filter 26 and the output is delivered to the outlet 28 of the chip 12 to a waveguide. film, and the laser can have higher frequency modulation speed in the frequency modulation process and ensure the frequency modulation linearity.

### Linear Performance.

For the device of FIG. 1, the intrinsic quality (Q) factor of the racetrack resonators may be around 1.2 million, while the external coupling Q may be much lower, varying from 5.0×10⁴ to 1.5×10⁵, which determines the loaded Q of the device. The laser light-current-voltage (LIV) curve measurement is performed for the lasing mode at 1581.12 nm, which has a threshold current of 80 mA and an on-chip power of around 3.7 mW at 200 mA. The highest on-chip power measured from this device can reach more than 5.5 mW by adjusting the Vernier mirror conditions.

The two racetrack resonators use different coupling structures: the first one uses a Pulley coupler, but the second racetrack adopts a straight waveguide coupler at both telecom and near-infrared wavelengths for SHG operation. Both bus waveguides are designed to work only for the fundamental quasi-TE mode. A pulley coupling structure benefits the bandwidth of the lasing spectrum, but also raises the risk of multi-mode lasing. Here, the use of the straight coupling design for one resonator significantly suppresses the mode that is one Vernier FSR away. With this design, single-mode laser is achieved, with a high side-mode suppression ratio (SMSR) greater than 50 dB. The coarse wavelength tuning is realized by thermo-optical tuning a Vernier ring resonator as described above, with a tuning range of ˜20 nm from 1576 nm to 1596 nm which agrees with the designed Vernier FSR (2.4 THz). The high SMSR is maintained over the entire tuning range.

The linewidth of the laser may be first characterized by a delayed self-heterodyne method with a particular setup. The recorded data is fit by a com-bination of Lorentzian and Gaussian distributions, resulting in a Lorentzian linewidth of 15.0 kHz. To confirm the linewidth, we further applied the correlated delayed self-heterodyne phase noise method. The recorded phase noise includes a white noise floor of ˜2×10³ Hz²/Hz at a frequency around 5 MHz, which corresponds to an intrinsic linewidth (or Lorentzian linewidth) of 12.6 kHz for the laser, further confirming the narrow-linewidth performance.

### Ultrafast Frequency Tuning and Switching of the Laser.

There is an urgent demand for high-speed linear modulation of laser frequency in various applications, such as the FMCW approach in LiDAR and the optical frequency domain reflectometry (OFDR). The Pockels laser is ideal for this purpose, where the laser frequency can be fast tuned by electro-optically tuning the phase shifter section. As such EO tuning of the phase shifter only changes the effective optical path length of the laser cavity while without introducing any loss, it offers an elegant approach for fast and pure tuning of laser frequency that is free from intensity modulation.

To show this capability, we apply a high-speed driving electrical signal to the phase shifter and monitor the laser-frequency tuning by beating the laser output with a reference narrow-linewidth laser whose frequency has a 8.0-GHz initial offset (details in SM). For a better illustration of the fine tuning performance via the Pockels effect, the driving electrical signal is in a triangular waveform with a modulation frequency ranging from 0.1 MHz to 1 GHz and an amplitude of VP=3.0 V. The heterodyne beat note is recorded and processed by a short time Fourier transform (STFT). Recorded data for the modulation frequency ranging from 1 MHz to 500 MHz, together with the deviation of laser-frequency modulation linearity details that the waveform of laser-frequency modulation follows faithfully that of the driving electrical signal (dashed curves) at all frequencies, with a nonlinearity less than 10% for the modulation frequency up to 500 MHz with a lower driving voltage of VP=2.0 V, the nonlinearity of laser-frequency modulation can be reduced to 3%. The resolution of the spectrogram degrades with increased modulation speed, which is simply due to the limited sampling rate of the oscilloscope used to record the laser beating signal.

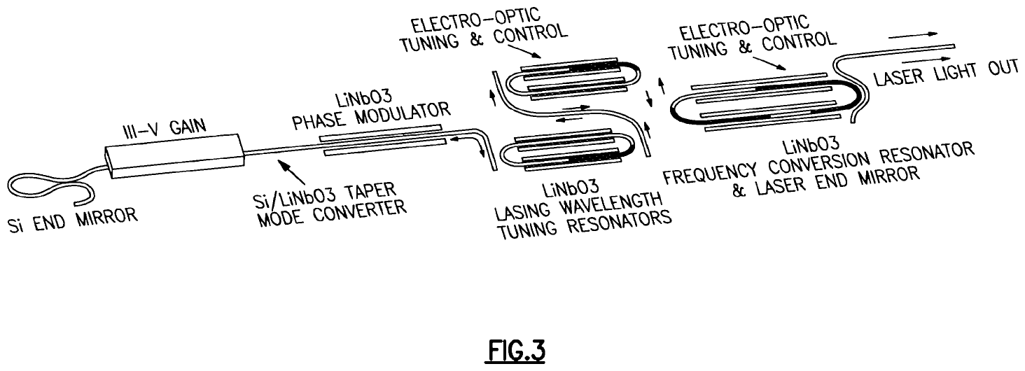

The amplitude of laser-frequency modulation remains at a fairly constant level across the broad range of modulation frequency up to 600 MHZ, with a value in the range of (1.6-2.0) GHz that corresponds to a tuning efficiency of (0.26-0.34) GHz/V. As a result, the laser-frequency modulation rate increases nearly linearly with modulation speed, reaching a value of 2.0 EHz/s (2.0×10¹⁸ Hz/s) at the modulation frequency of 600 MHZ. The frequency modulation rate starts to saturate when the modulation frequency increases beyond 700 MHZ, simply because the modulation speed reaches the photon lifetime limit of the laser cavity (estimated to be ˜0.2 ns), leading to a degradation of EO tuning efficiency (FIG. 3C).

The laser-frequency modulation of our laser is fairly independent of intensity modulation, since with direct phase modulation inside the cavity, the intensity variation of the laser is merely caused by the mode mismatch between the cavity longitudinal mode and the Vernier mode, which is fairly small within the bandwidth of the Vernier mode. Moreover, a continuous signal is observed, with a small amplitude variation less than 10%. This is in strong contrast to other frequency modulation approaches such as current modulation of diode laser that suffer from the considerable coexisting modulation, underlying the quality of related applications. The residual intensity modulation in the illustrated laser can be further suppressed by a coordinate EO tuning of the both the phase shifter and the Vernier ring resonator.

In addition to the pure frequency tuning shown above, the Pockels laser also allows a fast on-off switching of the lasing mode. This pure intensity modulation is realized by applying a square wave to electro-optically drive the racetrack resonator (instead of the phase shifter as done above. Details in SM). The consequential mode mismatch between two resonators introduces rapid degradation of Vernier mode, resulting in drastic change of the intra-cavity loss, which enables an on-off behavior of laser, acting as a high-speed switch. For example, with applied modulating frequencies ranging from 0.1 MHz to 50 MHz, both on- and off-states can be observed distinctly with a 10%-90% rise and fall times around 3 ns, limited by the speed of the applied driving signal (see SM). The switching performance degrades when the modulation frequency increases beyond 50 MHz, which is likely due to the oscillatory nature of the laser during cavity mode stabilization.

Further increase of the amplitude of the driving electrical signal would trigger the second adjacent lasing mode, leading to intriguing fast laser mode switching. For example, the amplitude of the driving square wave is increased to Vp=4 V, a value adequate to switch the laser between two lasing modes with frequencies 100 GHz apart.

To observe the switching behavior, the laser output is separated by a wavelength-division demultiplexer (WDM) into two channels at different wavelengths to monitor the dynamics of the individual lasing modes (details in SM). The switching between the adjacent laser modes is observed with a clear rising edge around 3 ns. The quality of signal is limited by the requirements of synchronous control on the phase shifter for longitudinal mode alignment, which can be implemented in future work. The fast wavelength switching demonstrated here is of great potential for application in data communication and access network.

### Dual Wavelength Laser.

In traditional integrated photonics, SHG can only be pumped using an external laser, which is complicated in operation and difficult to scale up. Here, for the first time, we incorporate PPLN directly into the integrated laser cavity, which enables inherent SHG by the integrated laser itself, significantly reducing the system complexity. Moreover, the strong intracavity laser power compared to the laser output can further enhance the SHG process. The resonance matching between the fundamental frequency (FF) and second harmonic (SH) modes for the SHG process is precisely controlled by the temperature of the laser chip. As soon as the device starts to lase at 1581.12 nm, the produced SH is readily visible at the output facet of the laser chip. The spectra of the fundamental telecom laser and the frequency-doubled visible wave exhibit a dual-wavelength lasing behavior. The recorded laser output at both wavelengths shows a clear quadratic power dependence between the two colors, an intrinsic nature of the SHG process. The power of generated SH light can be further increased by raising the Q factor of the racetrack resonator. With a 10-fold increase in external coupling Q to 0.6 million (critically coupled), a conversion efficiency of 15% can be obtained, corresponding to more than 1 mW SH power.

As the wavelength converter is embedded in the laser with fast tuning/switching capability, the Pockels laser thus offers fast reconfigurability of the visible light simply by manipulating its telecom pump laser as shown in the previous section. Among these capabilities, high-speed switching is particularly important for atomic/ion trapping experiments to conduct the imaging light controlling, optical pumping and brief laser cooling steps. To show this functionality, we apply a square-wave driving signal to modulate the lasing cavity and monitor the waveform of the frequency-doubled light (details in SM). The on-off switching is clearly observed with a modulation frequency from 0.1 MHz to 10 MHz, with defined waveforms. Such a switching speed can satisfy the speed requirement of almost all the atom/ion manipulating experiment.

### DISCUSSION

Besides the functions we presented here, the implementation of the Pockels effect into integrated laser can lead to more novel functionalities compared to previous integrated lasers. The capability of fast laser-frequency reconfigurability by the EO effect, combined with the intensity modulation by varying the current, potentially can enable fully integrated optical arbitrary waveform generator (AWG) on chip for communications and microwave photonics. The cavity design can be further optimized by engineering the quality factors of the ring resonators to support much higher speed modulation, while maintaining a narrow linewidth at the same level with those of current ECDLs. Furthermore, by changing the design of the PPLN inside the resonator, the pump can be frequency converted to a much broader spectrum range, through cascaded sum frequency generation to shorter wavelength at green or blue, or optical parametric oscillator to mid-IR wavelength. Such flexible wavelength generation on-chip can significantly relieve the difficulties in material growth and device processing of different laser epi structures.

In summary, by hybrid integration of a LN external cavity with a III-V RSOA, we demonstrated the first integrated Pockels laser. The device exhibits a great reconfigurability based on the EO effect, featuring a record-high laser-frequency tuning speed of 2.0 EHz/s and switching speed up to 50 MHz This exceptional performance affords a promising solution to LiDAR and many other applications. Moreover, by incorporating the high nonlinear frequency conversion capability of LN, the first multi-color laser with telecom and its SHG wavelength output is realized. The further combination of these two functions helps to demonstrate fast switching of the wavelength converter with up to 10 MHz speed, paving the path to applications of integrated light sources for atomic physics, AR/VR and sensing.

The demonstrations in this work not only extend the ap-plications of the LNOI platform, but more generally, provide a solution to various problems in nanophotonics. They also provide a design path to multi-color fully integrated systems with various functionalities. Such systems have many potential applications in nonlinear optics, optical signal processing systems, quantum photonics and optical communications.

### Supplementary Materials

Device fabrication. The devices were fabricated on a 600-nm-thick x-cut single-crystalline LN thin film bonded on a 4.7-μm silicon dioxide layer sitting on a silicon substrate (from NanoLN). The waveguide and racetrack structures are patterned by ZEP-520A positive resist via electron-beam lithography; an Ar+ plasma milling process is used to transfer the pattern to the LN layer with the etch depth of 300-nm. The resist was removed by the solvent 1165 resist remover afterward. The metal electrode layer (10 nm Ti/500 nm Au) was patterned by PMMA and deposited by an electron-beam evaporator, then formed by an overnight lift-off process. Finally, the devices were diced and polished to minimize the edge coupling loss.

### Spot Size Converter

The mode mismatch can cause enormous insertion loss between the RSOA and LNOI chip, which degrades the output power of laser seriously. To resolve this potential issue, we introduce a spot-size converter to the system to match the mode profile at the edge of the RSOA. A minimal mode mismatch is found by the implementation of an input waveguide with 5 μm width and 600 nm thickness of LN thin film, simulated by an FEM software. With an etch depth of LN over 200 nm, minor variation to the matching efficiency is observed, allowing us to employ it to various designs simply.

### Laser Linewidth Measurement.

For example, the lasing signal passes a 50:50 splitter. One optical path is delayed by a 40-km-long fiber delay line, while the other is modulated by an acoustic optic modulator (AOM) at 55 MHz. The 40 km delay line realizes a low linewidth measurement down to 5 kHz, while the AOM is used to apply a frequency detuning to the signal, resulting in a radio frequency after recombination, which is relatively free from technical noise from electronics, vibrations, and other environmental factors. The signals are recombined by a 50:50 coupler and detected by a high-speed photodetector, then analyzed by an electrical signal analyzer. The recorded data is fit by a combination of Lorentzian and Gaussian distributions, resulting in a Lorentzian linewidth of 15.0 kHz.

For the correlated delayed self-heterodyne phase noise measurement, the optical path is delayed by a 1-km-long fiber line, and the signal is processed using a real-time oscilloscope. The frequency noise may be calculated from the phase noise. The white noise floor of ˜2×10³ Hz²/Hz is found at a frequency around 5 MHz. This value can be multiplied by 2π to indicate the intrinsic linewidth, or Lorentzian linewidth of the laser, which is 12.6 kHz in this case. The loaded optical Q of this device is measured to be ˜7.0×10⁴. As a comparison, we recorded a larger laser linewidth of 41 kHz for another laser device with a lower optical Q of ˜2.5×10⁴. A higher loaded Q results in a narrower laser linewidth, which can be further improved in future work.

Characterization of the linearity of laser frequency modulation. The laser frequency modulation is realized by electro-optically modulating the phase shifter of the device. The electrical driving signal with a triangular waveform is generated by a high-speed arbitrary waveform generator (AWG) (Keysight M8196A) and is amplified to aimed voltage amplitudes by a wide-band RF amplifier before it is applied to the phase shifter. Due to the limited bandwidth, the RF amplifier introduces certain distortions to the signal waveform. We first characterize such distortion by comparing the signal waveform with a perfect triangular waveform. Their difference, normalized by the peak-peak amplitude, is defined as Deviation 1, which quantifies the magnitude of waveform distortion of the electrical driving signal. Deviation 1 serves as the reference to characterize the linearity of laser frequency modulation (see below). Since the signal waveform is purely periodic, the waveform of Deviation 1 can be fully represented within one modulation period. To have a better accuracy, it is obtained by averaging over multiple modulation periods.

The beat note between the Pockels laser and the reference ECDL is recorded by a real-time oscilloscope (Keysight UXR0334A). The recorded signal is processed by STFT to retrieve the time-frequency spectro-gram. It is compared with a perfect triangular waveform, and their difference, normalized by the peak-peak amplitude, gives Deviation 2. The difference between Deviation 2 and Deviation 1 thus characterizes the linearity of laser frequency modulation. In illustrative embodiments, the net deviation is less than 10% at all measured frequencies, indicating a high linearity of laser frequency modulation over a large frequency tuning range. Moreover, of one's preference, a higher linearity can be achieved by sacrificing the tuning range, where a 3% deviation may be obtained with a 1.2-GHz detuning range.

Switching performance characterization. The lasing mode switching behavior may be explored. A square wave is produced by a function generator (Keysight 22621A) and applied to the electrodes sitting beside the resonator. By controlling the wavelength mismatch between two resonators, the lasing mode can be switched from one to another at minimum and maximum values of the square wave respectively. The lasing signal is then divided by a WDM and converted to electrical signal by two independent photodetector and recorded by a real-time oscilloscope.

The dual wavelength switching experiment is implemented with the similar setup via replacing the WDM and one of the photodetector by a visible band one (Thorlabs APD130A). For the recorded fundamental switching signals, the rise and fall time are defined by the bandwidth of function generator. In comparison, the ones of SHG light are limited by the bandwidth of the visible band photodetector, which are around 15 ns. Any observed spikes are signal over-shoot/undershoot caused by the same limitation, which are irrelevant to the performance of device.

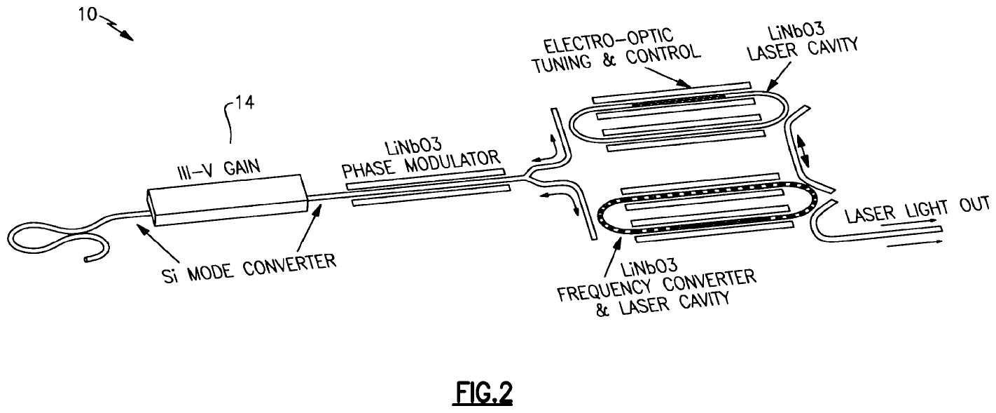

FIG. 2 illustrates another exemplative embodiment of the laser apparatus of the present disclosure. In illustrative embodiments, the Vernier resonator structure has a slightly different format but are still tuned by the electro-optic Pockels effect. Moreover, one or more of the resonators are periodically poled for nonlinear frequency conversion inside the laser cavity.

FIG. 3 illustrates another exemplative embodiment of the laser apparatus of the present disclosure. In this embodiment, the Vernier resonator structure functions purely as EO tuning elements while the end mirror of the laser cavity becomes the frequency converter. On the other hand, the III-V gain element can be integrated with the LN external laser cavity by different approaches, either by edge coupling as schematically shown in FIG. 1, or by heterogeneous integrated on the top of the LN waveguide structure as shown in FIGS. 2 and 3.

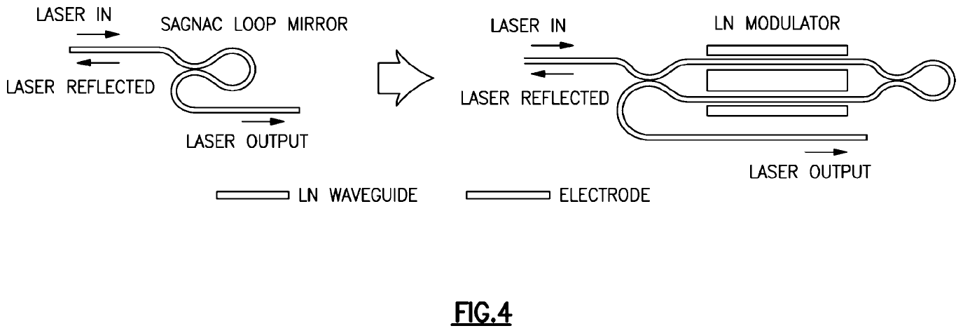

FIG. 4 illustrates another alternate embodiment in which the Sagnac loop mirror can be replaced by one with integrated LN modulator for EO tuning the mirror reflectivity.

In illustrative embodiments of the present inventions, the LN laser cavity exhibits the following novel characteristics that do not exist in previous integrated semiconductor lasers:
Ultrafast laser frequency tuning by fast EO tuning of the phase shifter, or by coordinated EO tuning of the phase shifter and the Vernier resonator(s).
Ultrafast laser mode switching by fast EO tuning/modulation of the Vernier resonator(s), or by coordinated EO tuning/modulation of the Vernier resonator(s) and the phase shifter.
Highly efficient intracavity laser frequency conversion, by utilizing the intracavity laser power that is significantly higher than the laser output.
Multi-color lasing at both the fundamental frequency and the converted laser frequency.
Ultra-fast tuning of multi-color lasing characteristics by fast EO tuning of the end mirror.

In illustrative embodiments, a laser apparatus, comprises a lithium-niobate-on-insulator (LNOI) substrate having a III/V gain element, a Vernier mirror structure on the (LNOI) substrate, including two or more microresonators each having one or more tuning electrodes. At least one of the microresonators is tuned by an electro-optic Pockels effect of lithium niobate (LN) in the cavity structure of the LNOI substrate.

In embodiments, one of the microresonators is associated with a local heater, and is configured to be tuned by a thermo-optic effect facilitated by the local heater.

In other embodiments, the laser apparatus includes a phase shifter whose phase is tuned by the electro-optic Pockels effect of LN.

In certain embodiments, a Sagnac loop mirror is positioned adjacent an output end mirror of the cavity structure.

In some embodiments, the Vernier mirror structure is configured to EO tune the phase shifter, or by coordinated EO tuning of the phase shifter and the microresonators.

In other embodiments, the Vernier mirror structure is configured to EO tune the phase shifter, or by coordinated EO tuning of the phase shifter and the microresonators

In embodiments, the Vernier mirror structure is configured to perform ultrafast laser mode switching by fast EO tuning/modulation of the microresonators, or by coordinated EO tuning/modulation of the microresonators and the phase shifter.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the claims.

### PUBLICATIONS

D. T. Spencer, T. Drake, T. C. Briles, J. Stone, L. C. Sinclair, C. Fredrick, Q. Li, D. Westly, B. R. Ilic, A. Bluestone, N. Volet, T. Komljenovic, L. Chang, S. H. Lee, D. Y. Oh, M.-G. Suh, K. Y. Yang, M. H. P. Pfeiffer, T. J. Kippenberg, E. Norberg, L. Theogarajan, K. Vahala, N. R. Newbury, K. Srinivasan, J. E. Bowers, S. A. Diddams, S. B. Papp, An optical-frequency synthesizer using integrated photonics. Nature 557, 81-85 (2018).
C. Xiang, J. Liu, J. Guo, L. Chang, R. N. Wang, W. Weng, J. Peters, W. Xie, Z. Zhang, J. Riemensberger, J. Selvidge, T. J. Kippenberg, J. E. Bowers, Laser soliton microcombs heterogeneously integrated on silicon. Science 373, 99-103 (2021).
Z. L. Newman, V. Maurice, T. Drake, J. R. Stone, T. C. Briles, D. T. Spencer, C. Fredrick, Q. Li, D. Westly, B. R. Ilic, B. Shen, M.-G. Suh, K. Y. Yang, C. Johnson, D. MS Johnson, L. Hollberg, K. J. Vahala, K. Srinivasan, S. A. Diddams, J. Kitching, S. B. Papp, M. T. Hummon, Architecture for the photonic integration of an optical atomic clock. Optica 6, 680-685 (2019).
R. N. Hall, G. E. Fenner, J. D. Kingsley, T. J. Soltys, R. O. Carlson, Coherent Light Emission from GaAs Junctions. Phys. Rev. Lett. 9, 366 (1962).
A. Yariv, Quantum Electronics (3rd Ed.), New York: Holt, Reinhart and Wilson, (1985).
L. Coldren, Diode Lasers and Photonic Integrated Circuits (3rd Ed.), John Wiley & Sons, (2012).
M. Smit, X. Leijtens, E. Bente, J. Van der Tol, H. Ambrosius, D. Robbins, M. Wale, N. Grote, M. Schell, Generic foundry model for InP-based photonics. IET Optoelectronics 5, 187-194 (2011).
S. Keyvaninia, G. Roelkens, D. Van Thourhout, C. Jany, M. Lamponi, A. Le Liepvre, F. Lelarge, D. Make, G.-H. Duan, D. Bordel, J.-M. Fedeli, Demonstration of a heterogeneously integrated III-V/SOI single wavelength tunable laser. Opt. Express 21, 3784-3792 (2013).
J. C. Hulme, J. K. Doylend, J. E. Bowers, Widely tunable Vernier ring laser on hybrid silicon. Opt. Express 21, 19718-19722 (2013).
M. A. Tran, D. Huang, J. E. Bowers, Tutorial on narrow linewidth tunable semiconductor lasers using Si/III-V heterogeneous integration. APL Photon. 4, 111101 (2019).
T. Chu, N. Fujioka, and M. Ishizaka, Compact, lower-power-consumption wavelength tunable laser fabricated with silicon photonic-wire waveguide micro-ring resonators,” Opt. Express 17, 14063-14068 (2009).
S. Tanaka, S.-H. Jeong, S. Sekiguchi, T. Kurahashi, Y. Tanaka, and K. Morito, High-output-power, single-wavelength silicon hybrid laser using precise flip-chip bonding technology, Opt. Express 20, 28057-28069 (2012).
M. Fleming, A. Mooradian, Spectral characteristics of external-cavity controlled semiconductor lasers, IEEE J. Quantum Electron. 17, 44-59 (1981).
Karen Liu and Michael G. Littman, Novel geometry for single-mode scanning of tunable lasers. Opt. Lett. 6, 117-118 (1981).
H. Guan, A. Novack, T. Galfsky, Y. Ma, S. Fathololoumi, A. Horth,
T. N. Huynh, J. Roman, R. Shi, M. Caverley, Y. Liu, T. Baehr-Jones, K. Bergman, M. Hochberg, Widely-tunable, narrow-linewidth III-V/silicon hybrid external-cavity laser for coherent communication. Opt. Express 26, 7920-7933 (2018).
D. Huang, M. A. Tran, J. Guo, J. Peters, T. Komljenovic, A. Malik, P. A. Morton, and J. E. Bowers, High-power sub-kHz linewidth lasers fully integrated on silicon. Optica 6, 745-752 (2019).
Y. Fan, A. van Rees, P. J. M. van der Slot, J. Mak, R. M. Oldenbeuving, M. Hoekman, D. Geskus, C. G. H. Roeloffzen, K.-J. Boller, Hybrid integrated InP-Si3N4 diode laser with a 40-Hz intrinsic linewidth. Opt. Express 28, 21713-21728 (2020).
B. Shen, L. Chang, J. Liu, H. Wang, Q.-F. Yang, C. Xiang, R. N. Wang, J. He, T. Liu, W. Xie, J. Guo, D. Kinghorn, L. Wu, Q.-X. Ji, T. J. Kippenberg, K. Vahala, and J. E. Bowers, Integrated turnkey soliton micro-combs. Nature 582, 365-369 (2020).
W. Jin, Q.-F. Yang, L. Chang, B. Shen, H. Wang, M. A. Leal, L. Wu, A. Feshali, M. Paniccia, K. J. Vahala, and J. E. Bowers, Hertz-linewidth semiconductor lasers using CMOS-ready ultra-high-q microresonators. Nature Photon. 15, 346-353 (2021).
Y. Gao, J.-C. Lo, S. Lee, R. Patel, L. Zhu, J. Nee, D. Tsou, R. Carney, and J. Sun, High-power, narrow-linewidth, miniaturized silicon photonic tunable laser With accurate frequency control, J. Lightwave Technol. 38, 265-271 (2020).
B. Stern, K. Kim, C. Cala, C. Fortin, D. Lanteri, K. Mekhazni, J. Provost, A. Wilk, F. Mallécot, F. Pommereau, A. Melikyan, P. Dong, Broadly and finely tunable hybrid silicon laser with nanosecond-scale switching speed. Opt. Lett. 45, 6198-6201 (2020).
J. X. B. Sia, X. Li, W. Wang, Z. Qiao, X. Guo, J. Zhou, C. G. Little-johns, C. Liu, G. T. Reed, and H. Wang, Sub-kHz linewidth, hybrid III-V/silicon wavelength-tunable laser diode operating at the application-rich 1647-1690 nm, Opt. Express 28, 25215-25224 (2020).
Y. Han, X. Zhang, F. Huang, X. Liu, M. Xu, Z. Lin, M. He, S. Yu, R. Wang, X. Cai, Electrically pumped widely tunable O-band hybrid lithium niobite/III-V laser. Opt. Lett. 46, 5413-5416 (2021).
C. O. Beeck, F. M. Mayor, S. Cuyvers, S. Poelman, J. F. Herrmann, O. Atalar, T. P. McKenna, B. Haq, W. Jiang, J. D. Witmer, G. Roelkens, A. H. Safavi-Naeini, R. V. Laer, B. Kuyken, III/V-on-lithium niobate amplifiers and lasers. Optica 8, 1288-1289 (2021).
Y. Koizumi, K. Toyoda, M. Yoshida, M. Nakazawa, 1024 QAM (60 Gbit/s) single-carrier coherent optical transmission over 150 km. Opt. Express 20, 12508-12514 (2012).
J. Riemensberger, A. Lukashchuk, M. Karpov, W. Weng, E. Lucas, J. Liu, T. J. Kippenberg, Massively parallel coherent laser ranging using a soliton microcomb. Nature 581, 164-170 (2020).
S. Dhoore, A. Koninger, Ralf Meyer, G. Roelkens, G. Morthier, Electronically Tunable Distributed Feedback (DFB) Laser on Silicon. Laser Photon. Rev. 13, 1800287 (2019).
W. J. Kozlovsky, C. D. Nabors, R. L. Byer, Efficient Second Harmonic Generation of a DiodeLaser-Pumped CW Nd: YAG Laser Using Monolithic MgO: LiNbO3 External Resonant Cavities. IEEE J. Quantum
Electron. 24, 913-919 (1988).
Q. H. Xue, Q. Zheng, Y. K. Bu, F. Q. Jia, L. S. Qian, High-power efficient diode-pumped Nd: YVO4/LiB3O5 457 nm blue laser with 4.6 W of output power. Optics Express 31, 1070-1072 (2006).
L. E. Myers, R. C. Eckardt, M. M. Fejer, R. L. Byer, W. R. Bosenberg, and J. W. Pierce, Quasi-phase-matched optical parametric oscillators in bulk periodically poled LiNbO3, J. Opt. Soc. Am. B 12, 2102-2116 (1995).
E. L. Wooten, K. M. Kissa, A. Yi-Yan, E. J. Murphy, D. A. Lafaw, P. F. Hallemeier, D. Maack, D. V. Attanasio, D. J. Fritz, G. J. McBrien, and D. E. Bossi, A review of lithium niobate modulators for fiber-optic communications systems, IEEE J. Sel. Top. Quant. Electron. 6, 69-82 (2000).
A. Boes, B. Corcoran, L. Chang, J. Bowers, and A. Mitchell, Status and Potential of Lithium Niobate on Insulator (LNOI) for Photonic Integrated Circuits, Laser Photon. Rev. 12, 1700256 (2018).
D. Zhu, L. Shao, M. Yu, R. Cheng, B. Desiatov, C. J. Xin, Y. Hu, J. Holzgrafe, S. Ghosh, A. Shams-Ansari, E. Puma, N. Sinclair, C. Reimer, M. Zhang, and M. Loncar, Integrated photonics on thin-film lithium niobate, Adv. Opt. Photon. 13, 242-352 (2021).
D. N. Nikogosyan, Nonlinear Optical Crystals: A Complete Survey, Springer-Science, (2005).
L. Richter, H. Mandelberg, M. Kruger, P. McGrath, Linewidth determination from self-heterodyne measurements with subcoherence delay times. IEEE J. Quantum Electron., 22, 2070-2074 (1986).
S. Camatel, V. Ferrero, Narrow linewidth CW laser phase noise characterization methods for coherent transmission system applications. J. Lightwave Technol. 26, 3048-3055 (2008).
W. Jin, Q. Yang, L. Chang, B. Shen, H. Wang, M. A. Leal, L. Wu, M. Gao, A. Feshali, M. Paniccia, K. J. Vahala, J. E. Bowers, Hertz-linewidth semiconductor lasers using CMOS-ready ultra-high-Q microresonators. Nature Photon. 15, 346-353 (2021).

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the claims.

What is claimed is:

1. A laser apparatus, which comprises:
a lithium-niobate-on-insulator (LNOI) substrate having a III/V gain element;
a Vernier mirror structure on the (LNOI) substrate, including:
two or more microresonators each having one or more tuning electrodes;
wherein at least one of the microresonators is tuned by an electro-optic Pockels effect of lithium niobate (LN) in the cavity structure of the LNOI substrate.

2. The laser apparatus according to claim 1 wherein one of the microresonators is associated with a local heater, and is configured to be tuned by a thermo-optic effect facilitated by the local heater.

3. The laser apparatus according to claim 2 including a phase shifter whose phase is tuned by the electro-optic Pockels effect of LN.

4. The laser apparatus according to claim 3 including a Sagnac loop mirror positioned adjacent an output end mirror of the cavity structure.

5. The laser apparatus according to claim 4 wherein the Vernier mirror structure is configured to EO tune the phase shifter, or by coordinated EO tuning of the phase shifter and the microsresonators.

6. The laser apparatus according to claim 4 wherein the Vernier mirror structure is configured to EO tune the phase shifter, or by coordinated EO tuning of the phase shifter and the microsresonators.

7. The laser apparatus according to claim 4 wherein the Vernier mirror structure is configured to perform ultrafast laser mode switching by fast EO tuning/modulation of the microresonators, or by coordinated EO tuning/modulation of the microresonators and the phase shifter.
